(19) United States
(12) Patent Application Publication
(10) Pub. No.: US 2006/0163698 A1
(43) Pub. Date: Jul. 27, 2006

(54) Method and apparatus for wafer to wafer bonding

(75) Inventor: Shinichi Araki, Sunnyvale, CA (US)

Correspondence Address: Trellis Intellectual Property Law Group, PC, 1900 EMBARCADERO ROAD, SUITE 109, PALO ALTO, CA, 94303, US

(73) Assignees: Sony Corporation, Tokyo (JP); Sony Electronics Inc., Park Ridge, NJ (US)

(21) Appl. No.: 11/043,748

(22) Filed: Jan. 25, 2005

(51) Int. Cl. H01L 23/544

(52) U.S. Cl. 257/620

(57) ABSTRACT

Inter-wafer structures are formed using semiconductor fabrication methods so as to provide precise, uniform distance between die on a bottom wafer and die on a top wafer. An inter-wafer structure layer is patterned to form one or more inter-wafer structures surrounding an active circuit area on a bottom die, or over an active circuit area on the bottom die, or both. The inter-wafer structures are formed as straight line shapes or as angled shapes. An adhesive layer is patterned to form an adhesive portion over the inter-wafer structures. The adhesive portion over the inter-wafer structures bonds a top die to the inter-wafer structures. The die include, for example, CMOS circuits and MEMS devices.

### BACKGROUND

This invention is related in general to semiconductor manufacturing processes and more specifically to a method and apparatus for wafer to wafer bonding.

Referring now to FIG. 1A, a conventional wafer to wafer electrostatic bonding approach is shown and indicated by the general reference character 100. For electrostatic bonding, when a moderate voltage is applied between two oxidized silicon wafers (e.g., Wafer 102 and Wafer 104), bonding is effectively induced at high temperatures (e.g., between 1100 and 1200 degrees C.). However, this approach does not allow for spacing the wafers during bonding.

Referring now to FIG. 1B, a conventional wafer to wafer bonding technique using a ball and glue is shown and indicated by the general reference character 150. In this approach, a periodic supply or a voltage pulse is used to attach the wafers. Ball 106 is, e.g., about 5 microns wide and made of silicon, metal, or another suitable material. Glue 108 is used to secure one or more balls 106 in place between the wafers 102 and 104. Although this approach allows spacing and bonding of the wafers, the size of the ball can typically vary by ±10%, so the space between the wafers cannot always be controlled to desired tolerances.

In general, establishing a precise, uniform distance (gap control) between two bonded wafers is difficult. Structure types other than balls have been used in an effort to improve on this gap controllability. In one approach, discrete shim spacers, such as glass rods, are glued in place or fabricated of photoresist on one of the wafer substrates. However, this approach does not fully solve the gap controllability problem because photoresist can be too soft to effectively maintain a gap spacing. In another approach, spacers can be used in positions outside of each die or chip on the wafer, but this approach can result in difficulties in positioning the spacers so as to provide a uniform gap.

### SUMMARY

In one embodiment, an inter-wafer structure substantially surrounds each die on a first wafer. The inter-wafer structure has an adhesive layer thereon, and both the inter-wafer structure and the adhesive layer are formed using the same semiconductor fabrication process used to fabricate electronic devices on the first wafer. A second wafer is bonded to the adhesive layer to the inter-wafer structure.

One embodiment of the invention provides an apparatus comprising: an inter-wafer structure disposed between at least two die on a first wafer; an adhesive layer fixedly coupled to at least a portion of the inter-wafer structure, the inter-wafer structure and adhesive layer being formed using a semiconductor fabrication process used to fabricate the first wafer; and a second wafer coupled by the adhesive layer to the inter-wafer structure.

In another embodiment of the present invention, a method of making wafer bonding structures using a semiconductor fabrication process includes: (i) applying an adhesive layer to a wafer; (ii) applying photoresist to the adhesive layer; (iii) patterning the photoresist; and (iv) etching through the adhesive layer and material below to form at least one inter-wafer structure.

In another embodiment of the invention, a method of bonding wafers includes: (i) forming an inter-wafer structure with an adhesive layer thereon on a first wafer using a semiconductor fabrication process used to fabricate the first wafer; and (ii) bonding a second wafer to the first wafer by the adhesive layer via the inter-wafer structure.

Embodiments of the invention can provide a wafer to wafer bonding technique using semiconductor fabrication for high gap controllability.

### BRIEF DESCRIPTION OF THE DRAWINGS

FIG. 1A shows a conventional wafer to wafer electrostatic bonding approach;

FIG. 1B shows a conventional wafer to wafer bonding technique using a ball and glue;

FIG. 2A shows an exemplary die gap inter-wafer structure arrangement in accordance with embodiments of the present invention;

FIG. 2B shows an exemplary intra-die inter-wafer structure arrangement in accordance with embodiments of the present invention;

FIG. 3A is a cross section diagram of an exemplary inter-wafer structure for the between die inter-wafer structure arrangement in accordance with embodiments of the present invention;

FIG. 3B is a cross section diagram of an exemplary inter-wafer structure for the intra-die inter-wafer structure arrangement in accordance with embodiments of the present invention;

FIG. 4 is a cross section diagram of an exemplary bonding arrangement between a CMOS wafer and a MEMS wafer in accordance with embodiments of the present invention;

FIG. 5 is a flow diagram of a process flow for making inter-wafer structures in accordance with embodiments of the present invention;

FIG. 6A is a cross section diagram of a step in the process of making inter-wafer structures in accordance with embodiments of the present invention; and

FIG. 6B is a cross section diagram of formed inter-wafer structures in accordance with embodiments of the present invention.

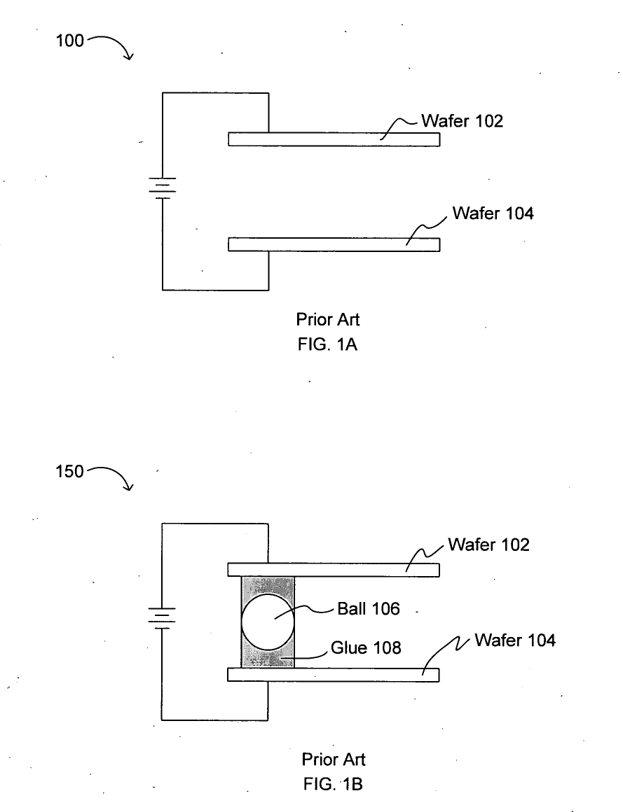

### DETAILED DESCRIPTION

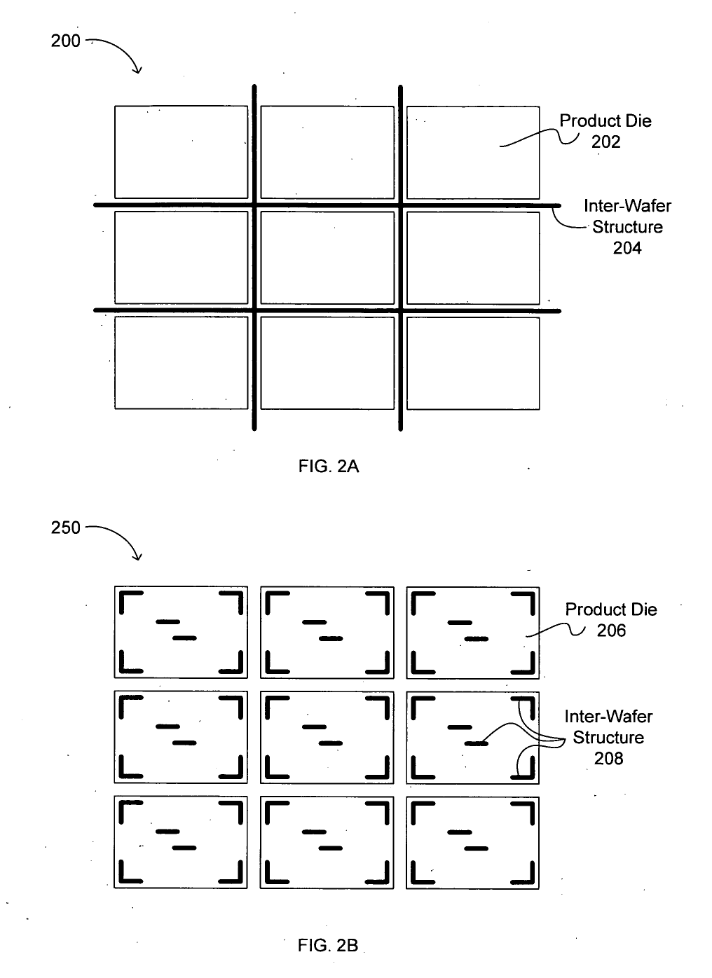

Referring now to FIG. 2A, an exemplary die gap inter-wafer structure arrangement in accordance with embodiments of the present invention is shown and indicated by the general reference character 200. A number of Product Die 202 are fabricated on the wafer to be bonded. In the space between each Product Die 202 (i.e., the scribe line), Inter-Wafer Structures 204 are located. Because Inter-Wafer Structures 204 extend and effectively surround each Product Die 202, a gap uniformity between wafers to be bonded can be well controlled.

Inter-Wafer Structures 204 can be made of any material suitable for uniform wafer gap control that is susceptible to a semiconductor manufacturing process. For example, silicon (Si), silicon dioxide (SiO₂), silicon nitride (SiN), or tungsten (W) may be used. In one embodiment, silicon or SiO₂ is used to form the “post” or inter-wafer structures.

Referring now to FIG. 2B, an exemplary intra-die inter-wafer structure arrangement in accordance with embodiments of the present invention is shown and indicated by the general reference character 250. These inter-wafer structures are placed over active circuitry, as will be discussed in more detail below. Here, Product Die 206 can each have a number of Inter-Wafer Structures 208 placed therein. For example, right angle shaped structures as illustrated in FIG. 2B, which provide a high degree of stability and wafer gap uniformity, are placed near the corners of each Product Die 206. In addition, for relatively large dice or chips, additional straight line shaped Inter-Wafer Structures 208 can be included in other parts of the Product Die 206, as illustrated in FIG. 2B. Further, any suitable shape for increasing control over the gap uniformity between wafers when bonded can be used for Inter-Wafer Structures 208 (see FIG. 2B) and 204 (see FIG. 2A).

Large wafer sizes can be bonded in accordance with embodiments of the invention. Further, diamond saw or laser-based cutting can be used to separate the individual die after the wafers have been bonded together. Also, inter-wafer structures can be placed in accordance with embodiments of the invention so that particles from a diamond cutting process are shielded from sensitive chip areas (e.g., microelectromechanical (MEM) mirrors). For example, a solid inter-wafer structure ring, as shown around the center die of FIG. 2A, around the entire die 202 can be used in some embodiments. In such instances, die 202 of FIG. 2A are separated by cutting inter-wafer structure 204 such that a portion of inter-wafer structure 204 remains with (i.e., surrounding) each die 202. As a result, the interior space between top and bottom die after bonding is sealed from the external environment. Such sealing is also beneficial during wafer cutting because it prevents unwanted material from entering the space between the die. Unwanted material can prevent proper microelectromechanical system (MEMS) device operation.

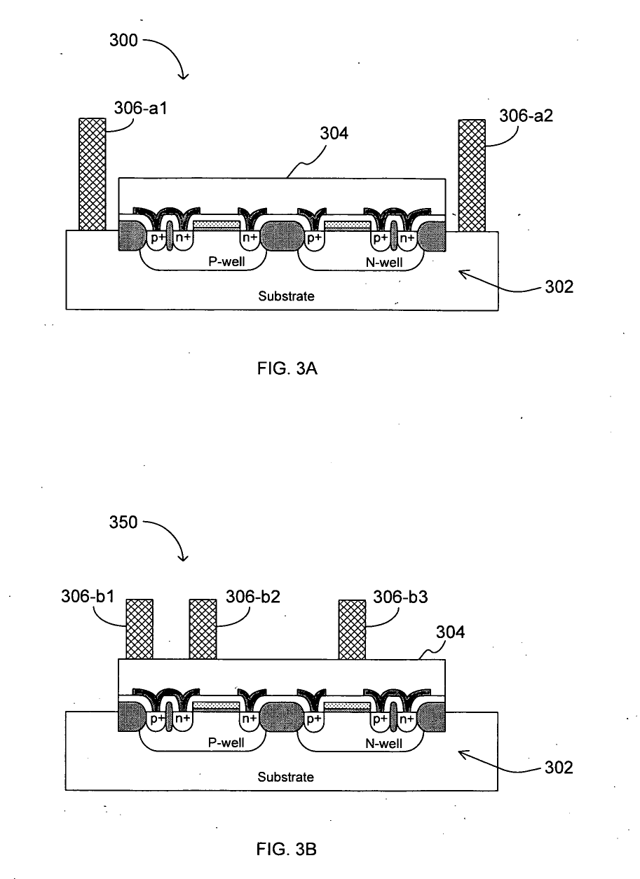

Referring now to FIG. 3A, a cross section diagram of an exemplary “post” or inter-wafer structure for the between die inter-wafer structure arrangement in accordance with embodiments of the present invention is shown and indicated by the general reference character 300. Wafer 302 can be a CMOS, BiCMOS, MEMS, or other type of wafer. The example is a conventional CMOS wafer cross section (PMOS and NMOS transistors are shown) along with passivation (e.g., silicon dioxide (SiO₂)) coating 304. In according with embodiments, the area between chips includes a surface that supports inter-wafer structures 306-a1 and 306-a2. These inter-wafer structures 306-a correspond to those in the die gap (i.e., scribe line) inter-wafer structure 204 arrangement of FIG. 2A. The inter-wafer structures can be made of silicon, glass, or any other material suitable for a semiconductor fabrication process.

Referring pow to FIG. 3B, a cross section diagram of an exemplary inter-wafer structure for the intra-die inter-wafer structure arrangement in accordance with embodiments of the present invention is shown and indicated by the general reference character 350. In this alternate embodiment, inter-wafer structures 306-b1, 306-b2, and 306-b3 are fabricated on top of coating 304, which is substantially over active circuitry components (e.g., transistors). These inter-wafer structures 306-b correspond to those in the intra-die inter-wafer structure 208 arrangement shown in FIG. 2B.

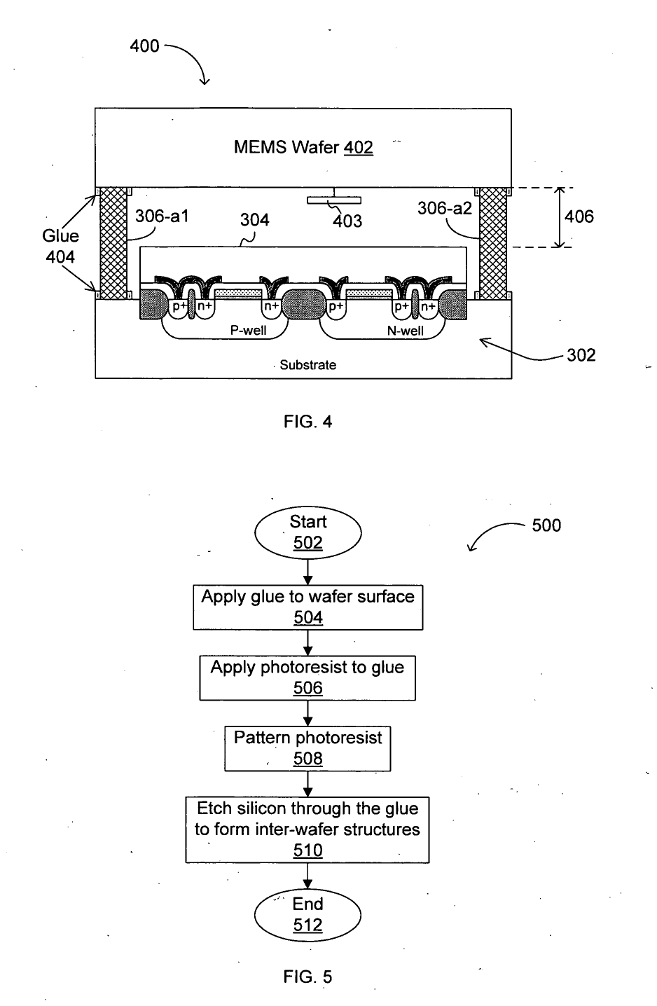

Referring now to FIG. 4, a cross section diagram of an exemplary bonding arrangement between a CMOS wafer and a MEMS wafer in accordance with embodiments of the present invention is shown and indicated by the general reference character 400. CMOS wafer 302 is bonded to MEMS Wafer 402 using inter-wafer structures 306-a1 and 306-a2. An illustrative MEMS structure (e.g., a movable mirror) 403 is positioned on MEMS wafer 402. To bond the wafers in place, adhesive material 404 (e.g., glue) is apportioned on one side of inter-wafer structures 306-a1 and 306-a2. The side (e.g., top or bottom as shown in FIG. 4) to which adhesive material 404 is applied depends on the wafer (e.g., CMOS wafer 302 and/or MEMS wafer 402) on which that particular inter-wafer structure 306-a is fabricated. For example, glue is applied to one surface (i.e., upper surface or lower surface) if all of inter-wafer structures 306-a1 and 306-a2 are fabricated on the same one of the wafers to be bonded together. In other words, inter-wafer structures 306-a1 and 306-a2 may be fabricated on CMOS wafer 302 and adhesive material 404 may be applied to the top of each of inter-wafer structures 306-a. Alternatively, inter-wafer structure 306-a1 may be fabricated on MEMS Wafer 402 and inter-wafer structure 306-a2 may be fabricated on CMOS wafer 302 so that an interlocking pattern of inter-wafer structures 306-a1 and 306-a2 is employed. As will be discussed in more detail below, adhesive material 404 is part of the wafer fabrication process in accordance with embodiments. A distance or wafer gap spacing 406 is then fixed with good control (i.e., from wafer to wafer and lot to lot) of the gap uniformity across the bonded wafer system 400.

Referring now to FIG. 5, a flow diagram of a process flow for making inter-wafer structures in accordance with embodiments of the present invention is shown and indicated by the general reference character 500. The flow begins in Start 502 and, at 504, glue is applied to the wafer surface. At 506, a layer of photoresist is then applied over the glue. Next, at 508 the photoresist is patterned using conventional processing techniques. Next, at 510 the silicon is etched based on the patterned photoresist to form the inter-wafer structures. The flow completes in End 512.

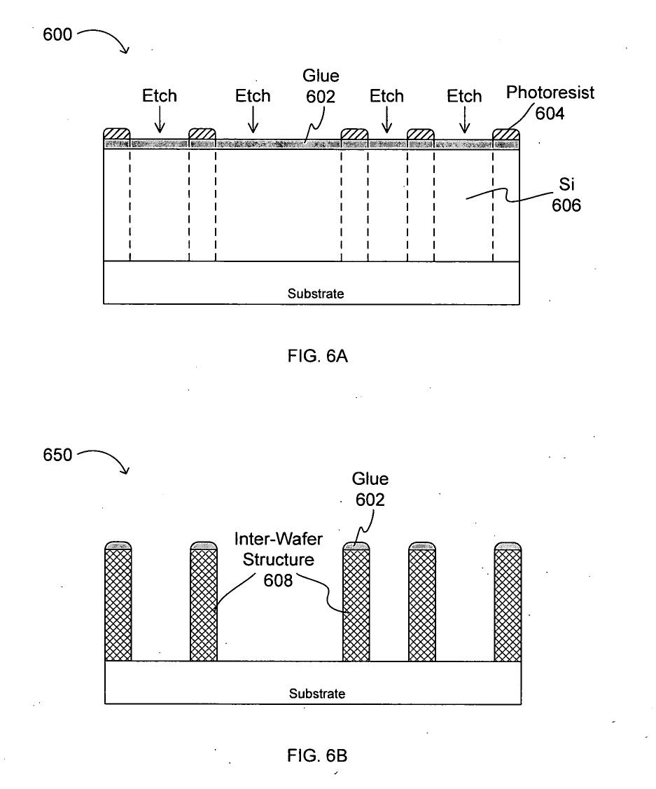

Referring now to FIG. 6A, a cross section diagram of a step in the process of making inter-wafer structures in accordance with embodiments of the present invention is shown and indicated by the general reference character 600. Glue 602 is a bonding layer, preferably applied by use of a sputtering process, over the wafer. Patterned Photoresist 604 defines the shape of the inter-wafer structures to be formed in silicon (Si) 606. Etching through the glue and partially through the silicon below then forms the inter-wafer structures.

Referring now to FIG. 6B, a cross section diagram of formed inter-wafer structures in accordance with embodiments of the present invention is shown and indicated by the general reference character 650. Remaining Glue 602 portions top each of Inter-Wafer Structures 608. Accordingly, Inter-Wafer Structures 608 are substantially made of silicon and each such silicon “post” is topped with an adhesive material (e.g., Glue 602) for bonding to another wafer.

Although the invention has been described with respect to specific embodiments thereof, these embodiments are merely illustrative, and not restrictive, of the invention. For example, although the invention has been discussed primarily with respect to silicon wafers, any type of wafer (e.g., silicon germanium (SiGe), gallium arsenide (GaAs), etc.) can be used in accordance with embodiments of the present invention to provide wafer to wafer bonding.

Further, technologies other than CMOS and/or MEMS can be used in accordance with embodiments. For example, BiCMOS wafers, MEMS to MEMS bonding, BiCMOS to MEMS bonding, or any other wafer to wafer bonding combination can be used.

Also, as used herein, “above,” “below,” “underlying,” “overlying” and the like are used primarily to describe possible relations between layers or structures therein, but should not be considered otherwise limiting. Such terms do not, for example, necessarily imply contact with or between elements or layers.

In the description herein, numerous specific details are provided, such as examples of components and/or methods, to provide a thorough understanding of embodiments of the present invention. One skilled in the relevant art will recognize, however, that an embodiment of the invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

Reference throughout this specification to “one embodiment”, “an embodiment”, or “a specific embodiment” means that a particular feature, structure, or characteristic described in connection with the embodiment is included in at least one embodiment of the present invention and not necessarily in all embodiments. Thus, respective appearances of the phrases “in one embodiment”, “in an embodiment”, or “in a specific embodiment” in various places throughout this specification are not necessarily referring to the same embodiment. Furthermore, the particular features, structures, or characteristics of any specific embodiment of the present invention may be combined in any suitable manner with one or more other embodiments. It is to be understood that other variations and modifications of the embodiments of the present invention described and illustrated herein are possible in light of the teachings herein and are to be considered as part of the spirit and scope of the present invention.

Embodiments of the invention may be implemented by using a programmed general purpose digital computer, by using application specific integrated circuits (ASICs), programmable logic devices (PLDs), field programmable gate arrays (FPGAs), optical, chemical, biological, quantum or nanoengineered systems, components and mechanisms may be used. In general, the functions of the present invention can be achieved by any means as is known in the art. Distributed, networked systems, and/or components and circuits can be used. Communication, or transfer, of data may be wired, wireless, or by any other means.

It will also be appreciated that one or more of the elements depicted in the drawings/figures can also be implemented in a more separated or integrated manner, or even removed or rendered as inoperable in certain cases, as is useful in accordance with a particular application. It is also within the spirit and scope of the present invention to implement a program or code that can be stored in a machine-readable medium to permit a computer to perform any of the methods described above.

Additionally, any signal arrows in the drawings/FIGS should be considered only as exemplary, and not limiting, unless otherwise specifically noted. Furthermore, the term “or” as used herein is generally intended to mean “and/or” unless otherwise indicated. Combinations of components or steps will also be considered as being noted, where terminology is foreseen as rendering the ability to separate or combine is unclear.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The foregoing description of illustrated embodiments of the present invention, including what is described in the Abstract, is not intended to be exhaustive or to limit the invention to the precise forms disclosed herein. While specific embodiments of, and examples for, the invention are described herein for illustrative purposes only, various equivalent modifications are possible within the spirit and scope of the present invention, as those skilled in the relevant art will recognize and appreciate. As indicated, these modifications may be made to the present invention in light of the foregoing description of illustrated embodiments of the present invention and are to be included within the spirit and scope of the present invention.

Thus, while the present invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the present invention. It is intended that the invention not be limited to the particular terms used in following claims and/or to the particular embodiment disclosed as the best mode contemplated for carrying out this invention, but that the invention will include any and all embodiments and equivalents falling within the scope of the appended claims.

What is claimed is:

1. An apparatus comprising:
an inter-wafer structure disposed between at least two die on a first wafer;
an adhesive layer fixedly coupled to at least a portion of the inter-wafer structure, the inter-wafer structure and adhesive layer being formed using a semiconductor fabrication process used to fabricate the first wafer; and
a second wafer coupled by the adhesive layer to the inter-wafer structure.

2. The apparatus of claim 1, wherein the inter-wafer structure is substantially within a scribe line separating the plurality of die.

3. The apparatus of claim 1, wherein the inter-wafer structure includes silicon.

4. A multi-wafer arrangement, comprising:
a plurality of inter-wafer structures substantially over active circuitry on a first wafer, each of the plurality of inter-wafer structures having an adhesive layer and being formed using a semiconductor fabrication process used to fabricate the first wafer; and
a second wafer coupled by each of the plurality of adhesive layers to each of the corresponding plurality of inter-wafer structures.

5. The multi-wafer arrangement of claim 4, wherein the plurality of inter-wafer structures includes substantially right angle shaped inter-wafer structures placed proximate to die corners.

6. The multi-wafer arrangement of claim 5, wherein the plurality of inter-wafer structures includes substantially straight structures proximate to die centers.

7. The multi-wafer arrangement of claim 4, wherein each of the plurality of inter-wafer structures includes silicon.

8. A method of making wafer bonding structures using a semiconductor fabrication process, comprising:
applying an adhesive layer to a wafer;
applying photoresist to the adhesive layer;
patterning the photoresist; and
etching through the adhesive layer and at least partially through material below to form at least one inter-wafer structure.

9. The method of claim 8, wherein the material below includes silicon.

10. A method of bonding wafers, comprising:
forming an inter-wafer structure with an adhesive layer thereon on a first wafer using a semiconductor fabrication process used to fabricate the first wafer; and
bonding a second wafer to the first wafer by the adhesive layer via the inter-wafer structure.

11. The method of claim 10, wherein the inter-wafer structure is over active die area.

12. The method of claim 10, wherein the inter-wafer structure substantially surrounds active die area.

13. An apparatus comprising:
a first die, the first die being cut from a first wafer;
an inter-wafer structure positioned on the first die, wherein the inter-wafer structure is continuously disposed around the perimeter of the die; and
a second die positioned over the inter-wafer structure, the second die being cut from a second wafer.

14. The apparatus of claim 13, wherein the second die comprises a microelectromechanical device.

15. The apparatus of claim 13 further comprising an adhesive layer between the inter-wafer structure and the second die.

16. An apparatus comprising:
a first die, the first die being cut from a first wafer;
a plurality of inter-wafer structures positioned on the first die, wherein the inter-wafer structures each comprise a straight line shape, and wherein the inter-wafer structures are positioned over active electronic devices formed in the first die; and
a second die positioned over the inter-wafer structure, the second die being cut from a second wafer.

17. The apparatus of claim 16, wherein the second die comprises a microelectromechanical device.

18. The apparatus of claim 16 further comprising an adhesive layer between each inter-wafer structure and the second die.

19. The apparatus of claim 16, wherein one of the inter-wafer structures comprises a substantially right angle shape, the right angle shape being between two straight line shapes.

20. A method comprising:
forming an inter-wafer support layer over a first wafer;
forming an adhesive layer over the inter-wafer support layer;
patterning the inter-wafer support layer and the adhesive layer to form an interlayer support and an adhesive layer portion over the interlayer support, wherein the patterned inter-wafer support comprises a straight-line shape; and
using the adhesive portion over the interlayer support to bond a second wafer to the inter-wafer support.
